(19) United States
(12) Patent Application Publication
(10) Pub. No.: US 2008/0280446 A1
(43) Pub. Date: Nov. 13, 2008

(54) METHOD OF PRODUCING A MICROSCOPIC HOLE IN A LAYER AND INTEGRATED DEVICE WITH A MICROSCOPIC HOLE IN A LAYER

(75) Inventors: Steffen Mueller, Dresden (DE); Odo Wunnicke, Dresden (DE); Henry Bernhardt, Dresden (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/745,800

(22) Filed: May 8, 2007

(51) Int. Cl. H01L 21/311; H01L 23/48

(52) U.S. Cl. 438/701; 257/774; 257/E23.01; 257/E21.249

(57) ABSTRACT

A microscopic hole is produced in a dielectric layer having a dielectric first material, a first surface and a second surface. In one embodiment, the tapered through-hole is etched from the second surface of the layer to the first surface of the layer. The tapered hole provides a first cross section near the first surface of the dielectric layer and a second cross section near the second surface of dielectric layer. A cladding is deposited at the inner surface of the through-hole. The cladding includes a second material and provides a thickness decreasing from the second surface to the first surface.

### SUMMARY

In one embodiment, a microscopic hole is produced in a dielectric layer having a dielectric first material, a first surface and a second surface. In one embodiment, the tapered through-hole is etched from the second surface of the layer to the first surface of the layer. The tapered hole provides a first cross section near the first surface of the dielectric layer and a second cross section near the second surface of dielectric layer. A cladding is deposited at the inner surface of the through-hole. The cladding includes a second material and provides a thickness decreasing from the second surface to the first surface.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a schematic representation of a vertical cross section of a layer with a hole.

FIG. 2 illustrates a schematic representation of a vertical cross section of a layer with a hole.

FIG. 3 illustrates a schematic representation of a vertical cross section of a layer with a hole.

FIG. 4 illustrates a schematic representation of a vertical cross section of a layer with a hole.

FIG. 5 illustrates a schematic representation of a vertical cross section of a layer with a hole.

FIG. 6 illustrates a schematic representation of a vertical cross section of a layer with a hole.

FIG. 7 illustrates a schematic representation of a vertical cross section of a layer with a hole.

FIG. 8 illustrates a schematic representation of a vertical cross section of a layer with a hole.

FIG. 9 illustrates a schematic representation of a vertical cross section through an integrated device.

FIG. 10 illustrates a schematic representation of a vertical cross section through o an integrated device.

FIG. 11 illustrates a schematic representation of a vertical cross section through o an integrated device.

FIG. 12 illustrates a schematic representation of a vertical cross section through an integrated device.

FIG. 13 illustrates a schematic representation of a vertical cross section through an integrated device.

FIG. 14 illustrates a schematic representation of a vertical cross section through o an integrated device.

FIG. 15 illustrates a schematic representation of a vertical cross section through an integrated device.

FIG. 16 illustrates a schematic representation of a vertical cross section through o an integrated device.

FIG. 17 illustrates a schematic representation of a vertical cross section through an integrated device.

FIG. 18 illustrates a schematic representation of a vertical cross section through an integrated device.

FIG. 19 illustrates a schematic representation of a vertical cross section through an integrated device.

FIG. 20 illustrates a schematic representation of a vertical cross section through an integrated device.

FIG. 21 illustrates a schematic representation of a vertical cross section of a layer with a hole.

FIG. 22 illustrates a schematic representation of a vertical cross section of a layer with a hole.

FIG. 23 illustrates a schematic representation of a vertical cross section of a layer with a hole.

FIG. 24 illustrates a schematic representation of a vertical cross section of a layer with a hole.

FIG. 25 illustrates a schematic flowchart of a method of producing an integrated device with a hole in a dielectric layer.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

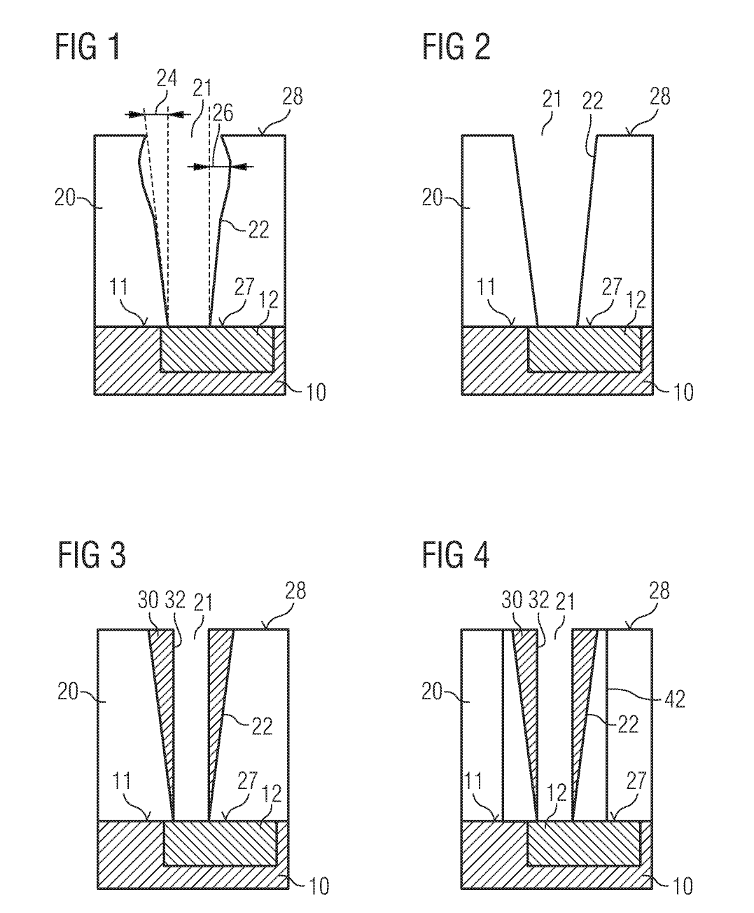

FIGS. 1 to 22 are schematic representations of vertical cross sections through integrated devices in different situations within or after a manufacturing process. Each integrated device includes a substrate 10 with a surface 11 and a switching device 12 arranged at the surface 11 of the substrate 10. The planes of the cross sections illustrated in the FIGS. 1 to 22 are vertical to the surfaces 11 of the substrates 10. The substrates 10 are semiconductor substrates (for example silicon Si, gallium arsenide GaAs, germanium Ge or any other doped or undoped or partly doped semiconductor) or any other material.

The electronic device 12 is for example a switching device like a field effect transistor or a bipolar transistor or any other electronic device. In case of a semiconductor substrate 10, the electronic device 12 is for example formed by one or several doped or undoped regions within the substrate 10 and/or at the surface 11 of the substrate 10. Although the surface 11 of the substrate 10 is illustrated in the FIGS. 1 to 20 as being flat, the surface 11 can be undulated or three-dimensional as well. Although the electronic device 12 is illustrated to be arranged below a surface 11 within the substrate 10, the electronic device 12 or parts of the electronic device 12 can project with respect to the surface 11 or with respect to a flat mean plane of the surface 11.

In some of the FIGS. 1 to 20, a dielectric layer 20 is arranged on the surface 11 of the substrate 10. A first surface of the dielectric layer 20 abuts on the surface 11 of the substrate 10. A second surface 28 of the dielectric layer 20 is opposed to the first surface 27. The dielectric layer 20 includes a dielectric material, for example undoped silicate glass (USG), silicon oxide (for example produced from tetraethyl orthosilicate TEOS) or other dielectric materials. The dielectric layer 20 can be deposited on the surface 11 of the substrate 10 using plasma enhanced chemical vapor deposition (PECVD) or other appropriate processes. The dielectric layer 20 may be provided for accommodating a capacitor, for example a capacitor of a memory cell of a memory device. As an alternative, the dielectric layer 20 accommodates a vertical contact electrically conductively connecting electrically conductive structures above and below the dielectric layer 20, for example structures in metallization layers or structures having highly doped semiconductor material. As a further alternative, the dielectric layer 20 serves as a hard mask for subsequent processing steps, for example for a patterning of the surface 11 of the substrate 10 by a dry etching process or for a laterally modulated implantation of a dopant into the substrate 10. As a further alternative, the dielectric layer 20 serves for other purposes.

Each of the integrated devices described below with reference to the FIGS. 1 to 20 can be larger or much larger than illustrated in the figures. In particular, each of the substrate 10 and the dielectric layer 20 can be laterally more or much more extended than illustrated in the figures. The FIGS. 1 to 20 are not to scale. The relation between the thickness of the substrate 10 and the thickness of the dielectric layer 20 as well as the height and width of the electronic device 12 can deviate from those illustrated in the figures.

FIG. 1 illustrates a hole 21 etched from the second surface 28 towards the first surface 27 of the dielectric layer 20 and connecting both surfaces 27, 28 of the dielectric layer 20. A part of the surface 11 of the substrate 10 and a part of the electronic device 12 are exposed through the hole 21. The hole 21 is, for example produced using reactive ion etching RIE.

The first contour 22 of the hole 21 deviates from a perfect cylindrical shape by a taper 24 and a bow 26. Both the taper 24 and the bow 26 can be due to an imperfectly anisotropic etching process. Due to the taper 24, the first contour 22 of the hole 21 is approximately conical. The cross section of the hole 21 at the second surface 28 of the dielectric layer 20 is larger than the cross section of the hole 21 at the first surface 27 of the dielectric layer 20. The bow 26 is a dilatation of the hole 21 near the second surface 28 of the dielectric layer 20.

In the FIGS. 2 to 4, holes 21 in the dielectric layer 20 are illustrated with a simplified first contour 22 merely providing a taper. Referring to FIG. 2, the dielectric layer 20 is illustrated with the hole 21 extending from the second surface 28 to the first surface 27 of the dielectric layer 20. The hole's 21 cross section at the second surface 28 is larger than the hole's 21 cross section at the first surface 27.

Referring to FIG. 3, a cladding 30 is deposited on the wall, or inner surface, of the hole 21. The material of the cladding 30 can be deposited on the second surface 28 of the dielectric layer 20, too. In this case, the material of the cladding 30 is removed from the second surface 28 of the dielectric layer 20 subsequently, for example, using a chemical mechanical polishing procedure. As an alternative, the material of the cladding 30 is deposited before a mask used for etching the hole is removed. When the mask is removed from the second surface 28 of the dielectric layer 20, the material of the cladding 30 is removed, too.

The cladding 30 includes a cladding material, for example aluminum oxide, aluminum nitride, silicon oxide or a mixture of aluminum oxide and silicon oxide. The cladding material is similar or equal to or different from the dielectric material of the dielectric layer 20. The thickness of the cladding 30 can be about 20 nm or less. However, the thickness of the cladding 30 can be more than 20 nm, too.

The cladding 30 provides a thickness decreasing from the second surface 28 to the first surface 27 of the dielectric layer 20. In FIG. 3, the thickness of the cladding 30 continuously decreases from the second surface 28 to the first surface 27 of the dielectric layer 20. To be more particular, the thickness of the cladding 30 is an essentially linear function of a z-coordinate, wherein the z-axis is vertical to the surfaces 27, 28 of the dielectric layer 20. Thereby, the cladding 30 reduces the taper of the hole 21. The inner surface of the cladding 30 is a second contour 32 of the hole 21.

The cross sections of the hole 21 and the cladding 30 illustrated in FIGS. 2 to 4 may be somewhat oversimplified. However, any shape of the cladding 30 with a thickness decreasing from the second surface 28 to the first surface 27 of the dielectric layer 20 reduces the taper of the hole 21 and causes the second contour 32 of the hole 21 to be more similar to the perfectly cylindrical contour. This is not only true for a cladding with a linearly decreasing thickness but also in case of a thickness which is not a linear function of the axial coordinate of the hole 21. Any cladding 30 with a continuously or even with an abruptly decreasing thickness may reduce the taper of the hole 21 and causes the contour of the hole to be more similar to a perfectly cylindrical contour.

After the deposition of the cladding 30, the hole 21 can be widened, for example by an isotropic etching process using BHF or any other appropriate etchant. FIG. 4 illustrates a third contour 42 of the hole 21 resulting after widening the hole. When the hole's 21 second contour 32 provided by the cladding 30 is nearly perfectly cylindrical (as illustrated in FIGS. 3 and 4), a nearly perfectly cylindrical third contour 32 is for example achieved when the etch rates of the dielectric material of the dielectric layer 20 and the cladding material of the cladding 30 are equal or essentially equal. When the hole's 21 second contour 32 provided by the cladding 30 is still tapered, an essentially cylindrical third contour 42 can be achieved by an etch rate of the cladding material which is lower than the etch rate of the dielectric material of the dielectric layer 20. When the cladding 30 overcompensates the taper of the hole 21, the hole's 21 cross section at the second surface 28 of the dielectric layer 20 is smaller than the hole's 21 cross section at the first surface 27. In this case, an essentially cylindrical third contour 42 may be achieved using an etch rate of the cladding material which is higher than the etch rate of the dielectric material. Even in case of a non-perfect compensation of the taper of the hole 21 and/or in case of an etch rate of the cladding material (slightly) higher than the etch rate of the dielectric material, the third contour 42 of the hole 21 can be less tapered and more cylindrical than the first contour 22.

According to the embodiment described above with reference to FIG. 4, the third contour 42 of the hole is outside the cladding 30. In other words, the cladding is completely removed after the widening of the hole 21. As an alternative, the cladding 30 can be removed partly, a part of the cladding 30 remaining. In this case, the third contour 42 of the hole 21 is not outside the cladding 30.

The FIGS. 5 to 8 illustrate a part of an integrated device in several situations during a process of manufacturing. Referring to FIG. 5, a dielectric layer 20 is deposited on a surface 11 of a substrate 10 with an electronic device 12. A first surface 27 of the dielectric layer 20 abuts on the surface 11 of the substrate 1O. A second surface 28 of the dielectric layer 20 is opposed to the first surface 27 of the dielectric layer 20.

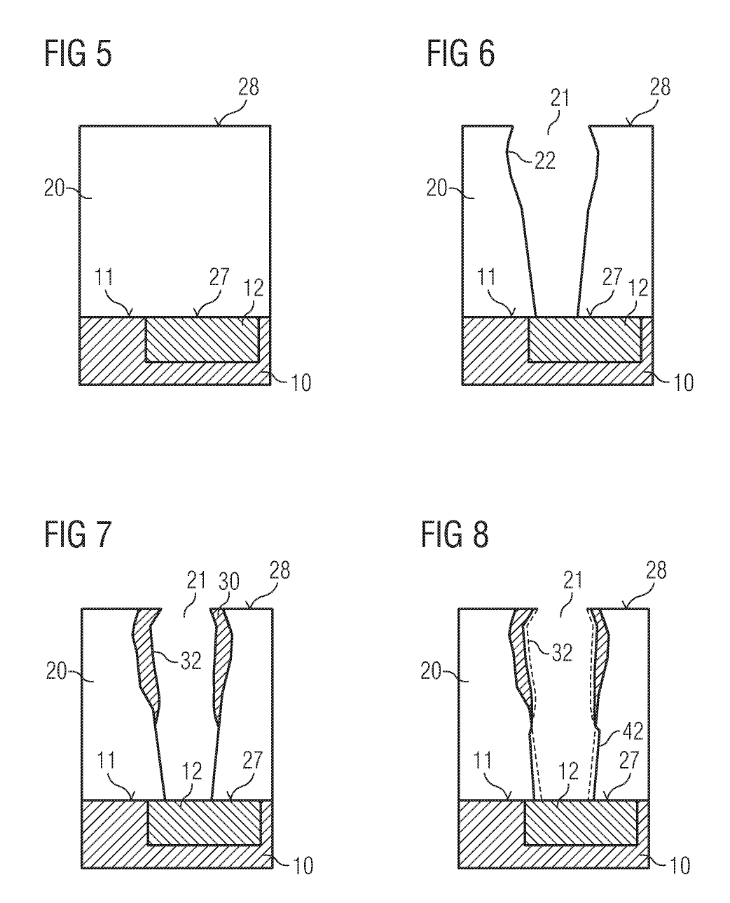

Referring to FIG. 6, the hole 21 providing a first contour 22 is provided in the dielectric layer 20, for example, using RIE or any other anisotropic etching process. The hole 21 is produced starting from the second surface 28 and extends to the first surface 27 of the dielectric layer 20 thereby exposing the surface 11 of the substrate 10 and the electronic device 12 at the surface 11. The first contour 22 of the hole 21 is illustrated in FIG. 6 to have both taper and bow.

Regarding FIG. 7, a cladding 30 having a cladding material is deposited on the wall of the hole 21. The cladding 30 provides a second contour 32 of the hole 21. The thickness of the cladding 30 decreases from the second surface 28 to the first surface 27 of the dielectric layer 20. To be more specific, the cladding 30 merely covers a first part of the inner wall of the hole 21, wherein the first part is located adjacent to the second surface 28 of dielectric layer 20. A second part of the inner wall of the hole 21 is not covered by the cladding 30. In other words, near the first surface 27 of the dielectric layer 20, a part of the second contour 32 is identical to the first contour 22.

As an example, the cladding 30 is produced using an atomic layer deposition (ALD) process with a precursor of the cladding material providing a high sticking coefficient and with a low concentration of the precursor in a carrier gas. The low concentration of the precursor and an appropriate pressure of the carrier gas provide for a steep concentration gradient within the hole 21 during the deposition of the precursor on the wall 21. The high sticking coefficient provides for a low mobility of the precursor on the wall of the hole 21. Both the low concentration of the precursor in the carrier gas and the high sticking coefficient facilitate the forming of the cladding 30 merely near the second surface 28 of the dielectric layer 20.

The profile of the cladding 30, in particular the thickness and the way the thickness decreases from the second surface 28 to the first surface 27 of the dielectric layer 20 can be adjusted by an appropriate choice of the process parameters. For example, a high sticking coefficient of a precursor tends to produce an sharp edge of the cladding with an abrupt reduction of the thickness to zero. A lower sticking coefficient tends to produce a smooth reduction of the thickness as for example illustrated in FIG. 3.

During the deposition of the cladding 30, the cladding material or the precursors of the cladding material, respectively, can be deposited on the second surface 28 of the dielectric layer 20, too. Illustrated in FIG. 7 is a situation after removing the cladding material from the second surface 28 of dielectric layer 20.

Referring to FIG. 8, the hole 21 is widened, for example by using an isotropic etching process. A third contour 32 results. The cross section of the hole 21 is increased by the widening. With an etch rate of the cladding material higher or at least slightly higher than the etch rate of the dielectric material, the cross section of the hole 21 near the first surface 27 of the dielectric layer 20 is increased more than the cross section of the hole 21 near the second surface 28 of the dielectric layer 20. Thereby, the third contour 42 of the hole 21 is even more similar to a cylinder than the second contour 32.

As can be seen from FIG. 8, a part of the cladding 30 remains after widening of the hole 21. Thereby, the third contour 42 is partly inside the first contour 22 and partly outside the first contour 22. As an alternative, the cladding 30 is completely removed in the process of widening. Thereby, the third contour 42 is completely outside the first contour 22.

The hole 21 with the second contour 32 or the third contour 42 as described above with reference to FIGS. 7 and 8 can be used as a hard mask for a subsequent structuring of the substrate 10. As an alternative, the hole 21 with the second contour 32 or the third contour 42 is filled with an electrically conductive material thereby forming an electrical contact between conductors or devices at the first and second surfaces 27, 28 of the dielectric layer 20. For example, the contact connects the electronic device 12 in or at the substrate 10 and a conductor or another device on the second surface 28 of the dielectric layer 20.

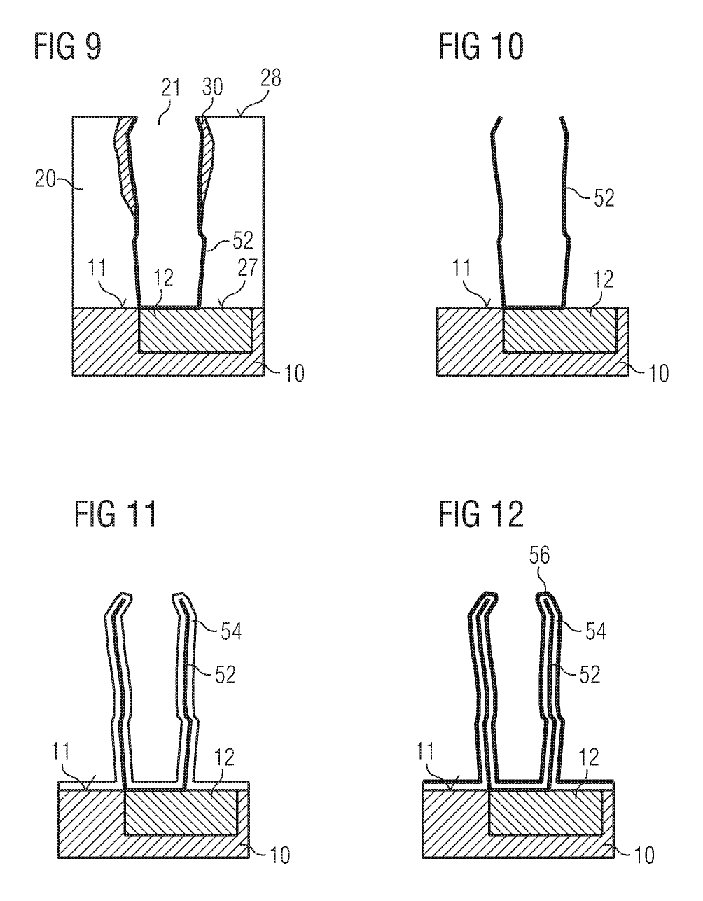

As a further alternative, a capacitor electrode is formed in the hole 21. Three exemplary alternative ways of forming a capacitor in or by using the hole 21 will be described below with reference to FIGS. 9 to 12, FIGS. 13 to 16 and FIGS. 17 to 20, respectively. Each of the methods described below with reference to the FIGS. 9 to 20 can start from the hole 21 with the second contour 32 as described above with reference to FIG. 3 as well as from the hole 21 with the third contour 42 as described above with reference to FIGS. 3 and 7 or from the hole 21 with the fourth contour 42 as described above with reference to FIGS. 4 and 8.

With reference to FIGS. 9 to 12 a manufacturing process of what is sometimes called a cylinder capacitor will be described. Referring to FIG. 9, a first electrode 52 having a metal or a metal alloy or a doped semiconductor or any other electrically conductive material is deposited on the inner wall of the hole 21 and on the exposed surface 11 of the substrate 10 thereby being electrically conductively connected to the electronic device 12. The electrically conductive material can be and usually is also deposited on the second surface 28 of the dielectric layer 20. In this case, the situation illustrated in FIG. 9 is achieved after removing the electrically conductive material from the second surface 28 of the dielectric layer 20, for example, using chemical mechanical polishing.

Referring to FIG. 10, the dielectric layer 20 is removed, for example, using a selective etching process not or essentially not wearing the electrically conductive material of the first electrode 52. Referring to FIG. 11, a dielectric film 54 is deposited on all exposed surfaces of the first electrode 52, the dielectric film for example having a high-k material. The dielectric film 54 can be deposited on the exposed parts of the surface 11 of the substrate 10, too. Referring to FIG. 12, a second electrode 56 having a metal or metal alloy or a doped semiconductor or any other electrically conductive material is deposited on the dielectric film 54. The second electrode 56 is electrically insulated from the first electrode 52 by the dielectric film 54. The first electrode 52 (connected to the electronic device 12) and the second electrode 56 (for example connected to ground or any other reference potential) form a capacitor. This capacitor is for example a storage capacitor of a memory cell. In this case, the electronic device 12 can be a switching device switchably connecting the first electrode 52 to a sense amplifier via a bit line.

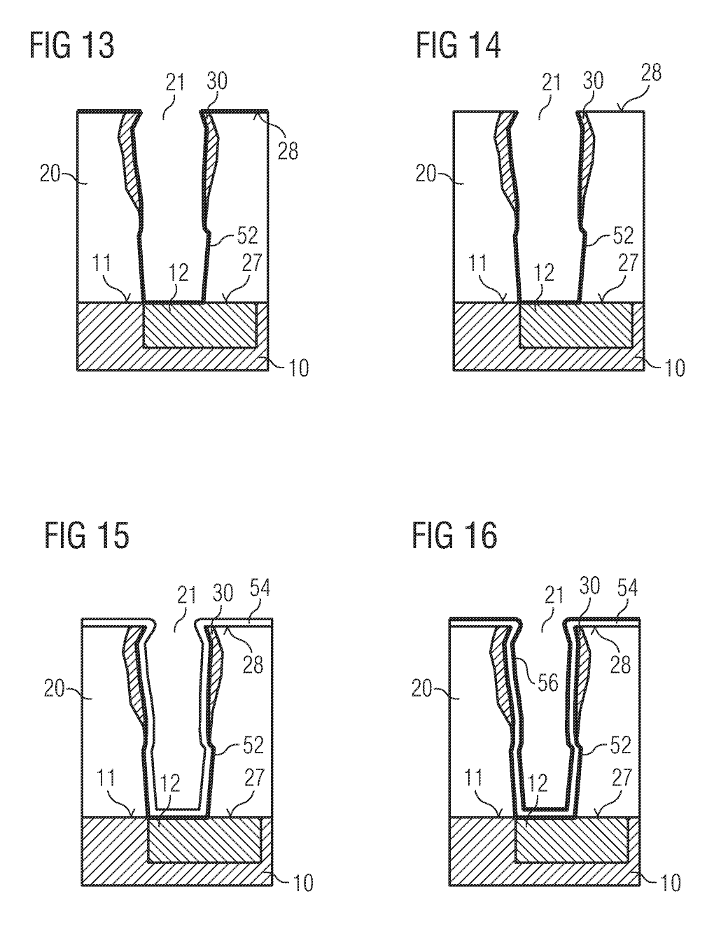

With reference to FIGS. 13 to 16, a method of manufacturing what is sometimes called a cup capacitor will be described. Referring to FIG. 13, a metal or metal alloy or a doped semiconductor or any other electrically conductive material is deposited on the wall of the hole 21, thereby forming a first electrode 52, and on the second surface 28 of the dielectric layer 20. The electrically conductive material is further deposited on the exposed parts of the surface 11 of the substrate 10 and of the electronic device 12 thereby forming an electrically conductive connection to the electronic device 12.

Referring to FIG. 14, the electrically conductive material on the second surface 28 of the dielectric layer 20 is removed, for example, using a chemical mechanical polishing process. Referring to FIG. 15, a dielectric film 54 is deposited on the first electrode 52 and on the second surface 28 of the dielectric layer 20, the dielectric film for example having a high-k material. Referring to FIG. 16, a second electrode having a metal or a metal alloy or a doped semiconductor or any other electrically conductive material is deposited on the dielectric film 54.

The second electrode 56 is electrically insulated from the first electrode 52 by the dielectric film 54. The first electrode 52 and the second electrode 56 (for example connected to ground or any other reference potential) form a capacitor, for example a capacitor of a memory cell. In this case, the electronic device 12 can be an electronic switch switchably connecting the first electrode 52 to a sense amplifier via a bit line.

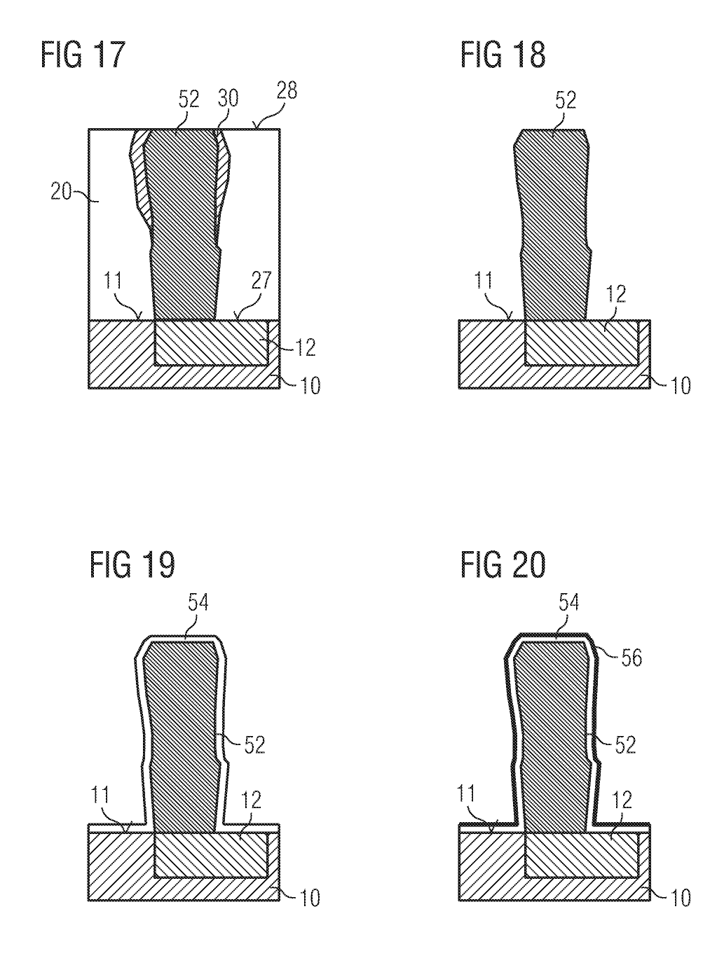

With reference to FIGS. 17 to 20, a process of manufacturing what is sometimes called a pod capacitor will be described. Referring to FIG. 17, a first electrode having a metal or a metal alloy or a doped semiconductor or any other electrically conductive material is deposited in the hole 21. Contrary to the embodiments described above with reference to FIGS. 9 to 12 and 13 to 16, the first electrode 52 is not only a layer or a thin film but fills the entire hole 21. The electrically conductive material of the first electrode 52 abuts on the exposed parts of the surface 11 and of the electronic device 12 thereby forming an electrically conductive connection to the electronic device 12. The electrically conductive material can be and usually is deposited on the second surface of the dielectric layer 20, too. In this case, the situation illustrated in FIG. 17 is the situation after removing the electrically conductive material from the second surface 28 of the dielectric layer 20, for example by a chemical mechanical polishing process.

Referring to FIG. 18, the dielectric layer 20 and the cladding 30 are removed, for example by a selective etching process not or essentially not wearing the material of the first electrode 52. Referring to FIG. 19, a dielectric film 54 is deposited on the first electrode 52, the dielectric film for example having a high-k material. The dielectric film 54 can be deposited on the exposed parts of the surface 11 of the substrate 10, too. Referring to FIG. 20, a second electrode 56 having a metal or a metal alloy or a doped semiconductor or any other electrically conductive material is deposited on the dielectric film 54. The second electrode 56 is electrically insulated from the first electrode 52 by the dielectric film 54. The first electrode 52 and the second electrode 56 (for example connected to ground or any other reference potential) form a capacitor, for example a capacitor of a memory cell. In this case, the electronic device 12 can be an electronic switch switchably connecting the first electrode 52 to a sense amplifier via a bit line.

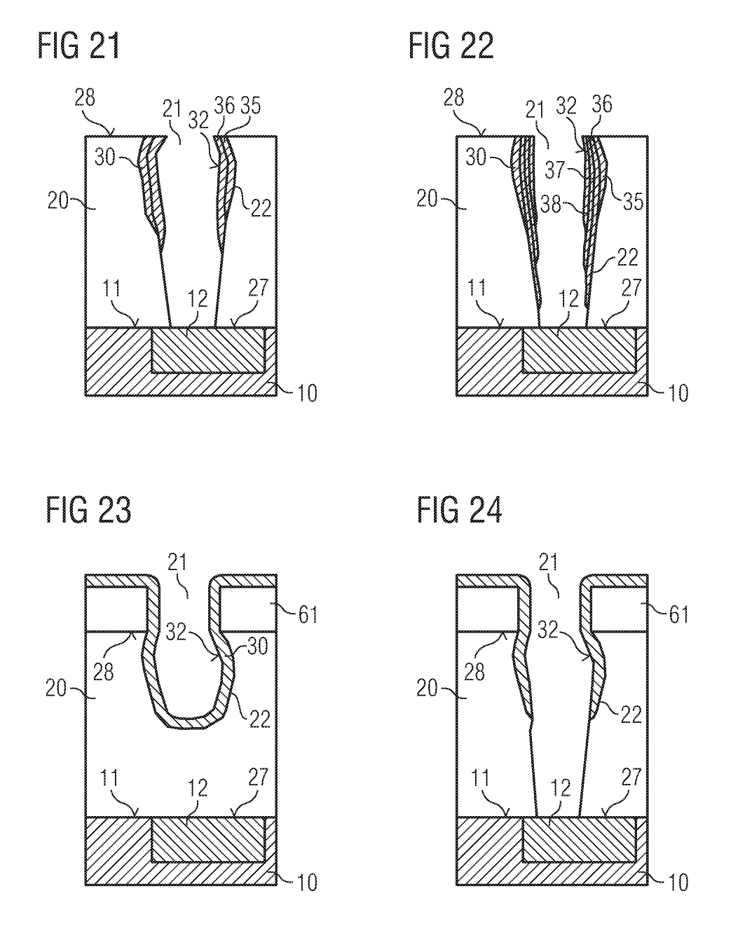

The cladding 30 can be formed as a homogenous member in one process (or in a sequence of consecutive ALD processes). As an alternative, the cladding 30 is formed of two or more cladding layers in separate processes. Referring to FIG. 21, the cladding 30 includes two cladding layer 35, 36, referring to FIG. 22, the cladding 30 includes four cladding layers 35, 36, 37, 38. The thickness and the depth (distance from the second surface 28 of the dielectric layer 20) to which any of the cladding layer 35, 36, 37, 38 extends can be set or adjusted via the processing conditions, for example the precursor, the concentration of the precursor, the pressure of the carrier gas, the temperature, the time etc. With appropriate values of the thickness of each cladding layer and the depth to which each cladding layer extends, the taper of the first contour 22 of the hole 21 can be compensated to a large extend.

The cladding layers 35, 36, 37, 38 can provide the same or a number of different materials. Each cladding layer can provide one of the materials described above with reference to FIG. 3 or any other material. As an example, at least one cladding layer 35, 36, 37, 38 includes aluminum oxide layer and at least one cladding layer 35, 36, 37, 38 includes silicon oxide.

A further alternative procedure of producing the cladding 30 will be described with reference to the FIGS. 23 and 24. Referring to FIG. 23, the hole 21 is etched into the dielectric layer 20, for example, using an RIE process or any other anisotropic etching process. A mask 61 (for example a photo resist mask) determines the cross section of the hole 21 at the second surface 28 of the dielectric layer 20. A similar mask may be used in the embodiments described above, too. Contrary to the embodiments described above, the hole does (initially) not extend to the surface 11 of the substrate 10. A cladding 30 is then deposited in the hole 21. As can be seen from FIG. 23, the cladding material can be deposited on the exposed surfaces of the mask 61, too.

Referring to FIG. 24, after depositing the cladding 30, the hole 21 is enlarged towards the first surface of the dielectric layer 20 and the surface of the substrate 10. Finally, the hole 21 exposes a part of the surface 11 of the substrate 10 and of the electronic device 12. In particular when the etch rate of the cladding material in the anisotropic etching process is lower than the etch rate of the dielectric layer, the formation of a taper is efficiently impeded or even prevented.

As an alternative, the process of etching the hole 21 can be stopped more than one time, each time depositing a cladding layer in the hole. In this way, the contour of the hole can be further optimized.

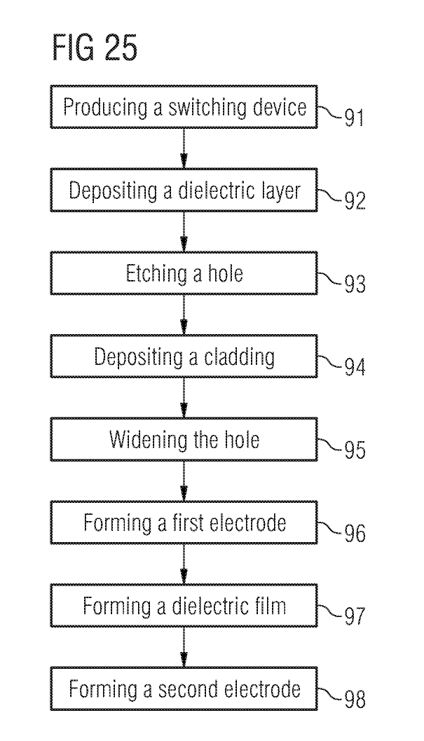

FIG. 25 is a schematic flow chart of a method of producing an integrated device. The method includes a method of producing a microscopic hole which can be used for other purposes as well. The method of producing an integrated device will be described in particular with reference to an integrated device with a memory cell but can be adopted for the production of other integrated devices as well.

In a first process 91, an electronic device 12 is produced at a surface 11 of a substrate 20. In case of the production of an integrated device with a memory cell, the electronic device 12 can be a switching device of the memory cell. In a second process 92, a dielectric layer 20 having a dielectric first material is deposited on the surface 11 of the substrate 10, wherein a first surface of the dielectric layer 20 abuts on the surface 11 of the substrate 10. In a third process 93, a tapered hole 21 is etched from a second surface 28 of the dielectric layer 20 to the first surface 27 of the dielectric layer 20. The tapered hole 21 provides a first cross section near the first surface 27 of the dielectric layer 20 and a second cross section near the second surface 28 of the dielectric layer 20. In a fourth process 94, a cladding 30 having a second material is deposited at the inner surface of the hole 21, wherein the cladding provides a thickness decreasing from the second surface 28 to the first surface 27. The cladding can reduce the variation of the cross section of the hole from the first surface 27 to the second surface 28. Thereby, the cladding can reduce a taper 24 and/or a bow 26 of the hole 21.

As can be seen from the embodiment described above with reference to the FIGS. 23 and 24, the third process 93 can be conducted in two sub-processes, wherein the fourth process 94 is conducted between theses sub-processes.

In an optional fifth process 95, the hole 21 is widened. The fifth process 95 can include an isotropic etching process. The first material (dielectric material of the dielectric layer 20) and the second material (cladding material of the cladding 30) can be selected such that the etch rate of the second material is lower than the etch rate of the first material. As an alternative, the etch rates of the first and second material are essentially equal or the etch rate of the second material is slightly higher or higher than the etch rate of the first material. In both cases, the cladding 30 can be removed partly or completely during the fifth process 95. When the etch rate of the second material is much lower than the etch rate of the first material, the cladding 30 is essentially not removed. Before the fifth process 95, the etch rates of the first and second materials can be modified or adjusted by heating the cladding 30 to an elevated temperature.

With or without the fifth process 95, the original taper and/or the original bow of the hole 21 can be compensated partly or even essentially completely. For example, the holes 21 cross section near the first surface 27 of the dielectric layer 20 essentially equals the inner cross section of the cladding 30 near the second surface 28.

While the first to fifth process 91 to 95 are part of a method of producing a microscopic hole 21, this hole can be used for forming a capacitor, for example a capacitor of a memory cell in subsequent processes. In a sixth process 96 a first electrode 52 is formed in the hole 21. In a seventh process 97, a dielectric film 54 is formed on the first electrode 52, the dielectric film 54 having a high-k material or any other dielectric material. In an eighth process 98, a second electrode 56 is formed on the dielectric film 54. Three examples for the sixth to eighth process 96 to 98 have been described above with reference to FIGS. 9 to 20.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of producing a microscopic hole in a dielectric layer comprising a dielectric first material, a first surface and a second surface, the method comprising:
etching a hole from the second surface of the layer to the first surface of the layer; and
depositing a cladding comprising a second material at the inner surface of the hole, the cladding providing a thickness decreasing from the second surface to the first surface.

2. The method as claimed in claim 1, wherein etching of the hole comprises etching the hole with a tapered contour, and wherein the taper of the hole is reduced by the cladding.

3. The method as claimed in claim 1, further comprising:
widening the hole using an etchant, wherein the etch rate of the second material essentially equals the etch rate of the first material.

4. The method as claimed in claim 1, further comprising:
widening the hole using an etchant, wherein the etch rate of the second material is lower than the etch rate of the first material.

5. The method as claimed in claim 4, wherein, in the process of widening, the cladding is completely removed.

6. The method as claimed in claim 4, wherein, in the process of widening, the cladding is partly removed.

7. The method as claimed in claim 1, wherein the cladding is deposited after a first part of the hole is etched, and wherein a second part of the hole is etched after the cladding is deposited.

8. The method as claimed in claim 1, further comprising:
heating the cladding to an elevated temperature; and
widening the hole by using an etchant.

9. The method as claimed in claim 7, wherein, in the process of widening, the cladding is completely removed.

10. The method as claimed in claim 1, wherein the cross-section of the hole near the first surface of the dielectric layer essentially equals the inner cross-section of the cladding near the second surface of the dielectric layer.

11. The method as claimed in claim 1, wherein the first material is an oxide.

12. The method as claimed in claim 1, wherein the hole is a hole in a hard mask or a through hole for a contact electrically conductively connecting electrically conductive structures.

13. The method as claimed in claim 1, wherein the second material comprises at least one of an aluminium oxide, an aluminium nitride, a silicon oxide and a mixture of aluminium oxide and silicon oxide.

14. The method as claimed in claim 1, wherein the process of depositing comprises depositing the cladding layer using an atomic layer deposition procedure.

15. The method as claimed in claim 1, wherein depositing the cladding comprises depositing a first cladding layer and depositing a second cladding layer.

16. A method of producing an integrated device with at least one capacitor, the method comprising:
depositing a dielectric layer comprising a dielectric first material on a surface of a substrate, a first surface of the dielectric layer abutting on the surface of the substrate;
etching a hole from a second surface of the dielectric layer to the first surface of the dielectric layer, the tapered hole providing a first cross-section near the first surface of the dielectric layer and a second cross-section near the second surface of the dielectric layer;
depositing a cladding comprising a second material at the inner surface of the hole, the cladding providing a thickness decreasing from the second surface to the first surface;
forming a first capacitor electrode by depositing an electrically conductive material in the hole;
forming a dielectric film on the first capacitor electrode; and
forming a second capacitor electrode on the dielectric film.

17. The method as claimed in claim 16, further comprising:
removing the dielectric layer after forming the first capacitor electrode.

18. The method as claimed in claim 16, wherein the first capacitor electrode is formed as a layer on the wall of the hole thereby providing essentially the shape of a hollow cylinder, and wherein the dielectric film and the second capacitor electrode are deposited on the inner wall and on the outer wall of this cylinder.

19. The method as claimed in claim 16, wherein the first capacitor electrode is formed as a plug filling the hole, and wherein the dielectric film and the second capacitor electrode are deposited on the outer surface of this plug after removing the dielectric layer.

20. The method as claimed in claim 16, wherein the first capacitor electrode is formed as a layer on the wall of the hole thereby providing essentially the shape of a hollow cylinder, and wherein the dielectric film and the second capacitor electrode are deposited on the inner wall of this cylinder and on the second surface of the dielectric layer.

21. Integrated device comprising:
a substrate;
a dielectric layer, a first surface of the dielectric layer abutting on the substrate;
a hole in the dielectric layer; and
a cladding in the hole, the cladding providing a thickness decreasing from a second surface to the first surface.

22. The integrated device as claimed in claim 21, wherein the cross-section of the hole near the first surface of the dielectric layer essentially equals the inner cross-section of the cladding near the second surface of the hole.

23. The integrated device as claimed in claim 21, wherein the dielectric layer comprises an oxide.

24. The integrated device as claimed in claim 21, wherein the hole is a through hole comprising a contact electrically conductively connecting a first structure at the first surface of the dielectric layer and a second structure at the second surface of the dielectric layer.

25. The integrated device as claimed in claim 21, wherein the cladding comprises a first cladding layer and a second cladding layer.

26. The integrated device as claimed in claim 21, further comprising a capacitor in the through hole of the dielectric layer.

27. The integrated device as claimed in claim 26, wherein the integrated device comprises a memory cell, and wherein the memory cell comprises the capacitor.

28. The integrated device as claimed in claim 27, configured as an electronic board.
